(19) United States
(12) Patent Application Publication
(10) Pub. No.: US 2025/0234688 A1
(43) Pub. Date: Jul. 17, 2025

(54) DISPLAY APPARATUS

(71) Applicant: LG Display Co., Ltd., Seoul (KR)

(72) Inventors: Changwoo Chun, Cheonan-si (KR); Giyoun Kim, Goyang-si (KR); Sejin Jang, Paju-si (KR)

(21) Appl. No.: 18/737,825

(22) Filed: Jun. 7, 2024

(30) Foreign Application Priority Data
Jan. 17, 2024 (KR) 10-2024-0007477

(51) Int. Cl. H01L 33/58; H01L 25/16; H01L 27/12

(52) U.S. Cl. CPC H10H 20/855; H01L 25/167; H10D 86/441; H10D 86/60

(57) ABSTRACT

Disclosed is a display apparatus having a substrate including a display area and a non-display area adjacent to the display area. Here, the substrate may be variable, pliable, rollable, flexible, foldable, stretchable, bendable, wearable, or the like. The display apparatus includes a plurality of connection wirings disposed on the substrate. The display apparatus includes a cover window disposed at least over the plurality of connection wirings. The display apparatus includes a light-blocking pattern part included in the cover window.

### CROSS-REFERENCE TO RELATED APPLICATION

This application claims priority to Korean Patent Application No. 10-2024-0007477 filed on Jan. 17, 2024, in the Korean Intellectual Property Office, the entire contents of which is hereby expressly incorporated by reference into the present application.

### BACKGROUND

### Technical Field

The present disclosure relates to a display apparatus, and more specifically, to a variable display apparatus.

### Description of the Related Art

Display apparatus is applied to various electronic apparatuses such as TVs, mobile phones, laptops, and tablets. To this end, research is continuing to develop display apparatus that are thinner, lighter, and have lower power consumption.

Examples of the display apparatus include liquid crystal display apparatus (LCD), field emission display apparatus (FED), and organic light-emitting display apparatus (OLED).

### BRIEF SUMMARY

Recently, research on a thin and light display panel has been actively conducted. Research on a variable display apparatus including a display panel such as a flexible display apparatus in which the display panel is bendable or curved, a rollable display apparatus in which the display panel is rollable, a foldable display apparatus in which the display panel is foldable, or a stretchable display apparatus in which the display panel is stretchable display apparatuses for use in electronic apparatuses such as wearable apparatuses, televisions, monitors, smartphones, tablet PCs, and laptops, as well as household items such as furniture is actively conducted. Thus, a wiring applied to the variable display apparatus is being developed to have a flexible structure. However, there is a problem in the related art that the wiring is visible to a viewer (or a user) or light reflected therefrom is visible to the viewer.

Various embodiments of the present disclosure address one or more technical problems in the related art including the problem identified above.

An aspect of the present disclosure is to provide a variable display apparatus in which the wiring is not visible to the viewer even when a stretching operation is repeated on the variable display apparatus.

Another aspect of the present disclosure is to provide a display apparatus that visibility of reflected light therefrom is reduced and an overall thickness of the display apparatus is reduced.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings,

To achieve these and other advantages and aspects of the present disclosure, as embodied and broadly described herein, a display apparatus may comprise a substrate including a display area and a non-display area adjacent to the display area, the substrate being variable (for example, the substrate is rollable, pliable, flexible, foldable, stretchable, bendable, wearable, or the like but not limited thereto, and thus the display panel and the display apparatus are also variable), a plurality of connection wirings disposed on the substrate, a cover window disposed at least over the plurality of connection wirings, and a light-blocking pattern included in the cover window.

According to an embodiment of the present disclosure, the light-blocking pattern part may be disposed such that a connection wiring disposed in a circuit area of the display apparatus (for example, a circuit area of the display panel) is not visible (in other words, the plurality of connection wirings disposed on the substrate are not visible) to a viewer (or user) even when the stretching operation is repeated on a variable display apparatus, thereby improving an immersion experience into an image of a user.

According to an embodiment of the present disclosure, the display apparatus may further comprise a plurality of first plate parts disposed on the display area of the substrate and including a plurality of sub-pixels, and a plurality of second plate parts disposed on the non-display area of the substrate.

According to an embodiment of the present disclosure, an overall thicknesses of a display apparatus may be reduced by integrating a light-blocking pattern part with a cover window. Accordingly, the display apparatus may be slimmed and lightweight, thereby reducing the weight of the display apparatus.

A light-blocking pattern part according to an embodiment of the present disclosure may have an increased area overlapping with a respective periphery of the first plate part and the second plate part. Thus, a connection wiring may be prevented from being visible to a viewer even when the length of the connection wiring increases in a stretching operation.

According to embodiments of the present disclosure, a light-blocking pattern part may be integrated into a cover window. Thus, a polarizer and a decoration film may be omitted, thereby simplifying a structure of the display apparatus. Accordingly, an overall thickness and overall weight of the display apparatus may be reduced, thereby reducing production energy thereof.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the present disclosure. Nothing in this section should be taken as a limitation on the present disclosure. Further aspects and advantages are discussed below in conjunction with aspects of the disclosure.

It is to be understood that both the foregoing description and the following description are examples and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 illustrates a configuration of a display apparatus according to some embodiments of the present disclosure.

FIG. 2 is an exploded perspective view of a display apparatus according to some embodiments of the present disclosure.

FIG. 3 is a plan view of a display apparatus according to some embodiments of the present disclosure.

FIG. 4 is an enlarged plan view of an area 4 in FIG. 3 according to some embodiments of the present disclosure.

FIG. 5 is a cross-sectional view taken along a line 5-5 in FIG. 4 according to some embodiments of the present disclosure.

FIG. 6 is a cross-sectional view taken along a line 6-6 in FIG. 4 according to some embodiments of the present disclosure.

FIG. 7 and FIG. 8 illustrate a display apparatus according to an embodiment of the present disclosure.

FIG. 9 and FIG. 10 illustrate a display apparatus according to another embodiment of the present disclosure.

FIG. 11 illustrates a display apparatus according to another embodiment of the present disclosure.

FIG. 12 illustrates a manufacturing method of a display apparatus in accordance with the present disclosure.

FIGS. 13 to 15 illustrate a way of forming a light-blocking pattern part according to some embodiments of the present disclosure.

FIG. 16 illustrates a light-blocking pattern part according to an embodiment of the present disclosure.

FIG. 17 illustrates an example of hysteresis characteristics according to some embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. However, the present disclosure may be embodied in different forms and should not be construed as limited to the embodiments set forth herein. Rather, these embodiments are examples and are provided so that this disclosure may be through and complete, to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise.

The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompass all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts may be located between two other parts unless a more limiting term, such as “immediate (ly),” “direct (ly),” or “close (ly),” is used. For example, when a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, may be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, may include all directions of “above” and “below.” Likewise, an exemplary term “above” or “on” may include both directions of “above” and “below.”

In describing a temporal relationship, when the temporal order is described as, for example, “after,” “subsequent,” “next,” “before,” “preceding,” “prior to,” or the like a case that is not consecutive or not sequential may be included and thus one or more other events may occur therebetween, unless a more limiting term, such as “just,” “immediate (ly),” or “direct (ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, members, parts, regions, areas, portions, steps, operations, and/or the like), these elements should not be limited by these terms, for example, to any particular order, sequence, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, or the like) is “provided,” “disposed,” “connected,” “coupled,” or the like in, on, with or to another element may be understood, for example, as that at least a portion of the element is provided, disposed, connected, coupled, or the like in another element, or that the entirety of the element is provided, disposed, connected, coupled, or the like in, on, with or to another element. The phrase that an element (e.g., layer, film, region, component, section, or the like) “contacts,” “overlaps,” or the like with another element may be understood, for example, as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure may operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by one or more of the first item, the second item, and the third item or (ii) only one of the first item, the second item, and the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some or some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of the various embodiments of the present disclosure may be partially or entirely coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly so defined herein.

The terms used in herein have been selected as being general in the related technical field. However, there may be other terms depending on the development and/or change of technology, convention, preference of technicians, etc. Therefore, the terms used herein should not be understood as limiting technical ideas, but should be understood as examples of the terms for describing example embodiments.

Further, in a specific case, a term may be arbitrarily selected by the applicant, and in this case, the detailed meaning thereof is described herein. Therefore, the terms used herein should be understood based on not only the name of the terms, but also the meaning of the terms and the content hereof.

In present disclosure, a display apparatus including a vibration apparatus may be implemented with a user interface device such as a central control panel in automobiles, and thus, may be applied to vehicles.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

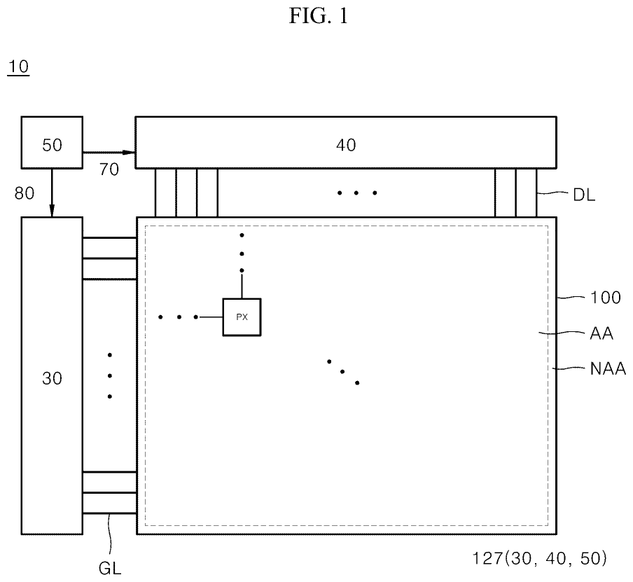

FIG. 1 illustrates a configuration of a display apparatus according to some embodiments of the present disclosure.

Referring to FIG. 1, a display apparatus 10 may include a display panel 100 including a display area AA and a non-display area NAA surrounding the display area AA, and a panel driver 127 configured to drive the display panel 100. The panel driver 127 may include a gate driver 30, a data driver 40, and a timing controller 50.

A plurality of signal lines may be disposed in the display panel 100. The plurality of signal lines may include a plurality of gate lines GL and a plurality of data lines DL. The plurality of gate lines GL may transmit a scan signal of the gate driver 30 to the display area AA, and the plurality of data lines DL may transmit a data signal of the data driver 40 to the display area AA. A pixel PX may be disposed in an area where the gate line GL and the data line DL intersect each other.

The pixel PX may include a plurality of sub-pixels. In one example, each of the plurality of sub-pixels may emit light in a wavelength range corresponding to one color among a plurality of colors different from each other. In this regard, the plurality of colors may include red color, green color, and blue color. In another example, the plurality of colors may further include white color.

A light-emitting element that emits a respective one of a plurality of colors may be disposed in each of the plurality of sub-pixels. In one example, the light-emitting element may be a light-emitting diode (LED) or a micro light-emitting diode (μLED). However, embodiments of the present disclosure are not limited thereto. The sub-pixel may include the light-emitting element and a circuit element such as a thin film transistor configured to drive the light-emitting element.

The timing controller 50 may control a driving timing of each of the gate driver 30 and the data driver 40.

For example, the timing controller 50 may supply a data control signal 70 configured to control an operation timing of the data driver 40 and supply a gate control signal 80 configured to control an operation timing of the gate driver 30, based on various timing signals received from an external source.

The gate driver 30 may control a driving timing of each of the plurality of sub-pixels by sequentially supplying a scan signal to the plurality of gate lines GL during one frame period for displaying an image based on the gate control signal 80. The gate driver 30 may be disposed at only one side (or one portion) or on each of both sides (or both portions) of the display panel 100.

The data driver 40 may convert an image data received from the timing controller 50 into an analog data voltage based on the data control signal 70. The data driver 40 may supply the data voltage to each data line DL according to a timing at which the scan signal is applied to each sub-pixel corresponding to each gate line GL.

The timing controller 50 may be mounted on a printed circuit board (for example, a flexible printed circuit board) and electrically connected to the gate driver 30 and the data driver 40.

The display apparatus 10 according to an embodiment of the present disclosure may be embodied as a variable display apparatus. For example, the variable display apparatus may include a rollable display apparatus, a foldable display apparatus, a bendable display apparatus, a curved display apparatus, a slidable display apparatus, or a stretchable display apparatus. However, embodiments of the present disclosure are not limited thereto. For example, an example in which the display apparatus is embodied as the stretchable display apparatus will be described. However, embodiments of the present disclosure are not limited thereto. The stretchable display apparatus may be a display apparatus that has stretchability and may be bent or stretched in any direction in which the user applies an external force, for example, in an up, down, left, or right direction, or diagonally. Furthermore, the stretchable display apparatus may display an image or video on the display area AA even when the display apparatus has been stretched under the external force applied to the display apparatus 10. Then, when the external force applied to the display apparatus 10 is removed, the display apparatus may be restored to its original form.

Due to the nature of the stretchable display apparatus which is bent or stretched in any direction in which the user applies the external force, when the external force is repeatedly applied thereto, a metal wiring disposed in a circuit area of the display apparatus (for example, a circuit area of the display panel) may be visible to the viewer, thereby reducing an immersion experience in the screen. In order to prevent the metal wiring, etc., from being visible to the viewer, a scheme has been proposed to reduce a thickness of a polarizer of the display apparatus and design the same to have a structure that the same may resist stretching. However, there is a limitation to how much the polarizer may be stretched. Additionally, it is possible to reduce reflection visibility in the circuit area by placing the polarizer between a cover window and the display panel, but when elongation of 5% or more is required, it is difficult to reduce reflection visibility through the polarizer. Accordingly, the present disclosure is to propose a configuration in which high elongation is achieved while preventing a connection wiring, for example, the metal wiring, etc., from being visible to the viewer.

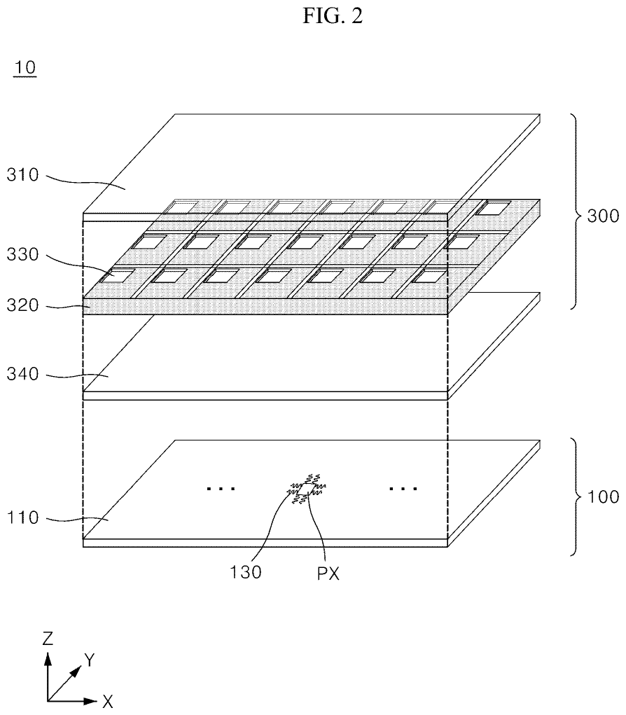

FIG. 2 is an exploded perspective view of a display apparatus according to some embodiments of the present disclosure.

Referring to FIG. 2, a display apparatus 10 according to an embodiment of the present disclosure may include a display panel 100 and a cover window 300 disposed on the display panel 100.

The display panel 100 may be stretched and thus may include a substrate 110 that is stretchable or variable (in this case, the display panel 100 is stretchable or variable), and a plurality of pixels PX configured to display an image and a plurality of circuits and a connection wiring 130 configured to drive the pixels PX may be disposed on the substrate 110.

The cover window 300 may be a member to protect the display panel 100. The cover window 300 may be in contact with the display panel 100. The cover window 300 may include a first cover member 310, a second cover member 340, and a light-blocking pattern part 320 disposed between the first cover member 310 and the second cover member 340.

The first cover member 310 may be disposed as an uppermost layer of the cover window 300 and may act as a surface visible to the viewer. The second cover member 340 may be disposed to be in contact with the display panel 100 and may protect various components of the display panel 100. The light-blocking pattern part 320 may be disposed between the first cover member 310 and the second cover member 340, and may prevent a plurality of circuit wirings and the connection wirings 130 disposed in the display panel 100 from being viewable or recognized by the viewer.

The first cover member 310 and the second cover member 340 of the cover window 300 may be formed of (or include) materials having different elastic modulus. In other words, the first cover member 310 and the second cover member 340 of the cover window 300 may have different elastic modulus. The first cover member 310 may be formed of (or include) a material having an elastic modulus which does not exceed a maximum of 5 MPa. In other words, the first cover member 310 may have an elastic modulus which does not exceed a maximum of 5 MPa. The second cover member 340 may be formed of (or include) a material having a modulus of 1 MPa or less, which is lower than that of the first cover member 310. In other words, the second cover member 340 may have an elastic modulus of 1 MPa or less.

For example, the first cover member 310 may be formed of (or include) an elastomer such as silicone rubber, or polydimethylsiloxane (PDMS) as a mixture of silicone and a curing agent. The second cover member 340 may be formed of (or include) an optically cleared adhesive (OCA) or an optically cleared resin (OCR).

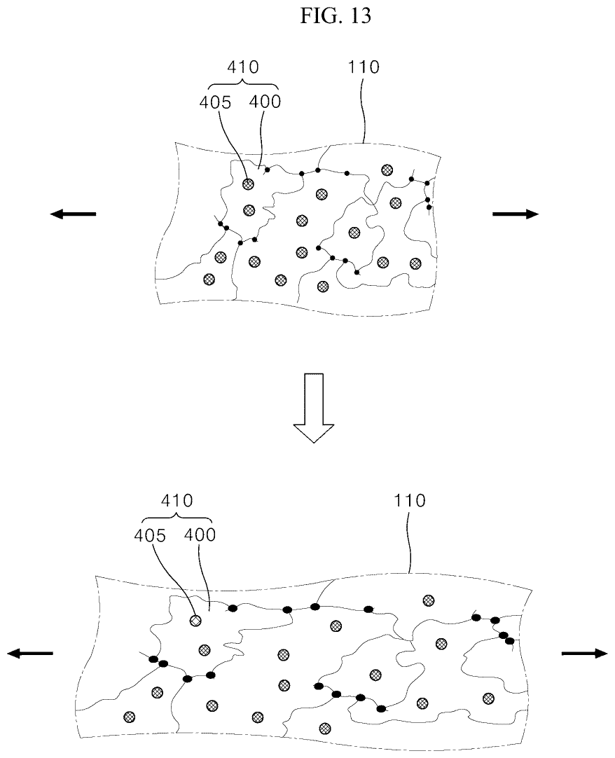

The light-blocking pattern part 320 may have an opening 330 through the light-blocking pattern part 320. The opening 330 may be a light emitting area where light emitted from a light-emitting element disposed in one of the plurality of sub-pixels constituting the pixel PX is emitted. The light-blocking pattern part 320 may be disposed across an entirety of the second cover member 340 excluding the opening 330 (in other words, may be disposed on an entire surface of the second cover member 340 excluding the opening 330). The light-blocking pattern part 320 may be formed of (or include) an opaque material with high elongation property. For example, the light-blocking pattern part 320 may be formed by a coating solution obtained by cross-linking a plurality of surface-treated black particles and a silicone solution with each other. This will be described in detail later with reference to FIGS. 13 to 15.

According to embodiments of the present disclosure, the light-blocking pattern part 320 may be disposed between the first cover member 310 and the second cover member 340, and the cover window 300 integrated with the light-blocking pattern part 320 may be bonded to the display panel 100, such that an overall thickness of the display apparatus 10 may be reduced.

According to embodiments of the present disclosure, since the stretchable display apparatus is free of a polarizer and a decoration film that are not easily stretched, the stretchable display apparatus may be easily constructed, and a structure of the display apparatus may be simplified.

Furthermore, due to the cover window 300 (which is variable) and the variable display panel 100, the variable display apparatus may display the image or video even when the display apparatus is bent or stretched in any direction.

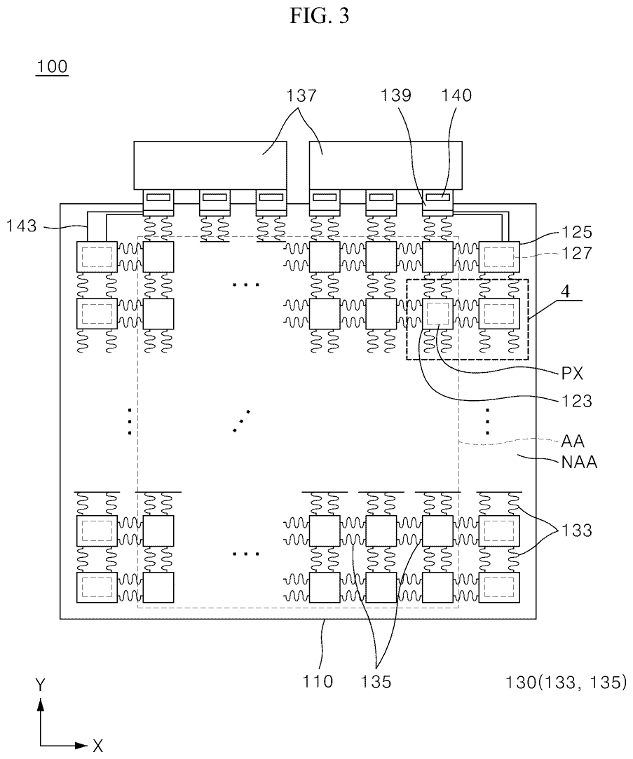

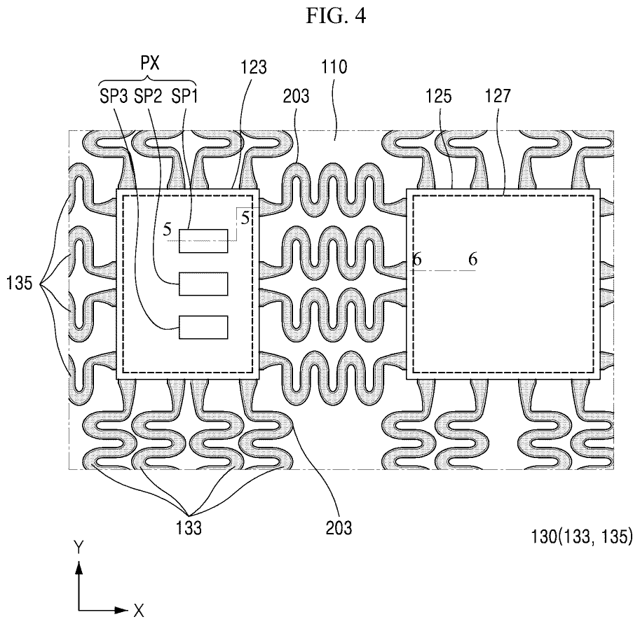

FIG. 3 is a plan view of a display apparatus according to some embodiments of the present disclosure. FIG. 4 is an enlarged plan view of an area 4 in FIG. 3 according to some embodiments of the present disclosure.

Referring to FIG. 3 and FIG. 4, a display panel 100 according to an embodiment of the present disclosure may include a substrate 110, a plurality of first plate parts 123, a plurality of pixels PX, a plurality of second plate parts 125, a panel driver 127, and a link wiring 143, a printed circuit board 137, a flexible circuit film 139, and an integrated circuit chip 140.

The substrate 110 may be a stretchable substrate and may be formed of (or include) a material that may be stretchable or bendable. The substrate 110 may be formed of silicone rubber, or polydimethylsiloxane (hereinafter, referred to as PDMS) as the mixture of silicone and a curing agent. However, embodiments of the present disclosure are not limited thereto. For example, any insulating material with flexible properties may be used for the substrate 110.

The substrate 110 may have a thickness of 200 μm to 350 μm. However, embodiments of the present disclosure are not limited thereto.

The substrate 110 may include a display area AA and a non-display area NAA. The display area AA may be an area where images are displayed and may constitute a center portion of the display panel 100. The plurality of pixels PX may be disposed in the display area AA. Each of the plurality of pixels PX may include a light-emitting element and a circuit element such as a transistor configured to drive the light-emitting element.

The non-display area NAA surrounds the display area AA. The non-display area NAA constitute an outer edge (or an outer periphery) of the display panel 100. However, embodiments of the present disclosure are not limited thereto. For example, the non-display area NAA may be an area where the circuit element is disposed.

The plurality of first plate parts 123 may be disposed on the display area AA of the substrate 110. The plurality of first plate parts 123 may be arranged to be spaced apart from each other. For example, the plurality of first plate parts 123 may be arranged in a first direction (e.g., X-axis direction) and a second direction (e.g., Y-axis direction). However, embodiments of the present disclosure are not limited thereto. The plurality of first plate parts 123 may be arranged in a matrix form. However, embodiments of the present disclosure are not limited thereto. For example, the first direction may be a horizontal direction or a row direction of the substrate 110, and the second direction may be a vertical direction or a column direction of the substrate 110.

The pixel PX may be disposed in each of the plurality of first plate parts 123. As shown in FIG. 4, the pixel PX may include a plurality of sub-pixels (for example, a first sub-pixel SP1, a second sub-pixel SP2, and a third sub-pixel SP3, but not limited thereto).

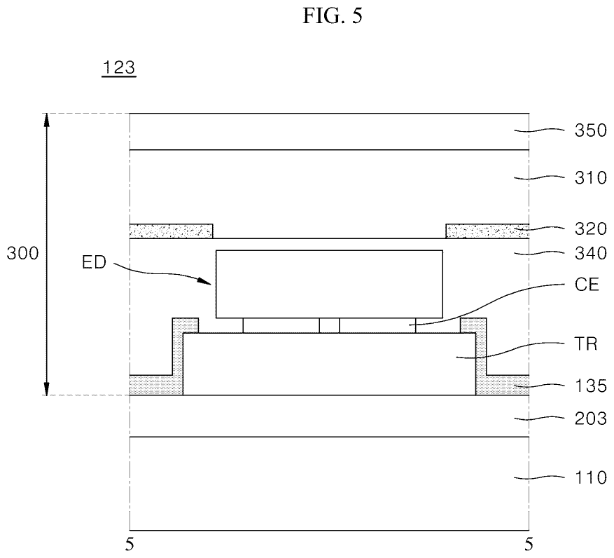

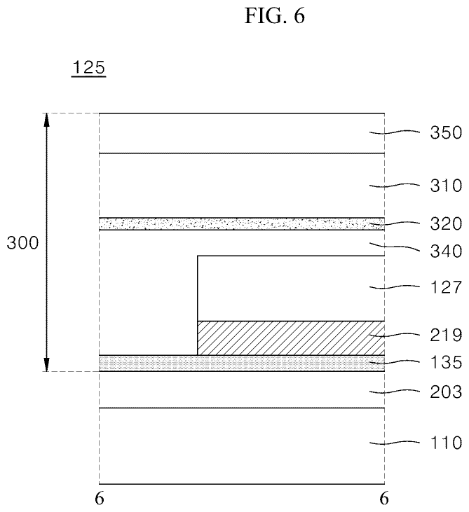

The first plate part 123 may be configured to be relatively more rigid than the substrate 110. Since the first plate part 123 may be relatively more rigid than the substrate 110, the first plate part 123 may be an area having a fixed shape. Accordingly, the first plate part 123 may maintain a constant (or a consistent) shape even when the display panel 100 is stretched or varied. Accordingly, a structure of the pixel PX disposed in the first plate part 123 may not be deformed or varied. The structure of each pixel PX will be described later with reference to FIG. 5 and FIG. 6.

Referring to FIG. 3, the plurality of second plate parts 125 may be disposed on the non-display area NAA of the substrate 110. The plurality of second plate parts 125 may be arranged to be spaced apart from each other. For example, the plurality of second plate parts 125 may be disposed on each of both sides (or both portions) of the substrate 110. For example, the plurality of second plate parts 125 may be arranged to be spaced apart from each other along the second direction (e.g., Y-axis direction) of the substrate 110. However, embodiments of the present disclosure are not limited thereto. Similar to the first plate part 123, the second plate part 125 may be configured to be relatively more rigid than the substrate 110.

The connection wiring 130 may be disposed between and connected to adjacent ones of the plurality of first plate parts 123. The connection wiring 130 may electrically connect adjacent ones of the plurality of first plate parts 123 disposed on the display area AA to each other. Furthermore, the connection wiring 130 may electrically connect adjacent ones of the plurality of second plate parts 125 disposed on the non-display area NAA to each other. Furthermore, the connection wiring 130 may electrically connect a respective second plate part 125 disposed on the non-display area NAA and a respective first plate part 123 disposed on the display area AA to each other.

The connection wiring 130 may include a first connection wiring 133 and a second connection wiring 135. The first connection wiring 133 may be a wiring extending in the Y-axis direction (the second direction) of the substrate 110. The second connection wiring 135 may be a wiring extending in the X-axis direction (the first direction) of the substrate 110. The connection wiring 130 may have a shape in which irregularities (or uneven portions) are continuously repeated or a concave-convex shape. For example, the connection wiring 130 may extend in a wave shape or a zigzag shape. However, embodiments of the present disclosure are not limited thereto.

Referring to FIG. 4, a rear surface (or a back surface) of each of the first connection wiring 133 and the second connection wiring 135 may be supported by a flexible substrate 203. When the flexible substrate 203 is used as a support member, the flexible substrate may have the same shape as that of a combination of the first connection wiring 133 and the second connection wiring 135. Accordingly, the substrate 110 may be exposed in an area other than an area where the first connection wiring 133 and the second connection wiring 135 are disposed.

The connection wiring 130 disposed between adjacent first plate parts 123 may be electrically connected to the light-emitting element and the circuit element such as the transistor disposed in the pixel PX. Furthermore, the first connection wiring 133 may be disposed between each of the first plate part 123 and the second plate part 125 and the printed circuit board 137 and may be electrically connected thereto.

The flexible circuit film 139 and the printed circuit board 137 may be disposed on at least one periphery (or at least one edge) of the non-display area NAA. The integrated circuit chip 140 may be disposed on the flexible circuit film 139. One side (or one portion) of the flexible circuit film 139 may be electrically connected or coupled to the first plate part 123, and the other side (or the other portion) thereof may be electrically connected or coupled to the printed circuit board 137. In one example, the flexible circuit film 139 may be electrically connected to the second plate part 125 via the link wiring 143. The flexible circuit film 139 and the first plate part 123 may be electrically connected to each other via the first connection wiring 133 extending in the second direction of the substrate 110.

The flexible circuit film 139 which is electrically connected to each of the first plate part 123 and the second plate part 125 may provide various powers and signals configured to drive the light-emitting element and supplied from the printed circuit board 137 to the first plate part 123 or the second plate part 125 which in turn may supply the various powers and signals to the display area AA. For example, the various powers and signals may include a high-potential voltage, a low-potential voltage, the scan signal, the data signal, etc. However, embodiments of the present disclosure are not limited thereto.

The printed circuit board 137 may supply signals to the integrated circuit chip 140 disposed on the flexible circuit film 139. Various components to supply the various signals to the integrated circuit chip 140 may be disposed in the printed circuit board 137. FIG. 3 shows a configuration in which the flexible circuit film 139 and the printed circuit board 137 are disposed only on one side edge (or a periphery portion) of the substrate 110. However, embodiments of the present disclosure are not limited thereto. For example, the flexible circuit film 139 and the printed circuit board 137 may be disposed on each of both opposite side edges (or both periphery portions) of the substrate 110.

The light-emitting elements that emit light of different colors may be respectively disposed in the plurality of sub-pixels (for example, the first sub-pixel SP1, the second sub-pixel SP2, and the third sub-pixel SP3, but not limited thereto) disposed on the first plate part 123.

FIG. 5 is a cross-sectional view along a line 5-5 in FIG. 4 according to some embodiments of the present disclosure. FIG. 6 is a cross-sectional view along a line 6-6 in FIG. 4 according to some embodiments of the present disclosure. FIG. 5 shows the light-emitting element and the transistor disposed in one sub-pixel for convenience of illustration. The plurality of sub-pixels may include substantially the same component.

Referring to FIG. 3 together with FIGS. 5 to 6, the plurality of first plate parts 123 may be disposed on the display area AA of the substrate 100. The plurality of first plate parts 123 may be disposed on the substrate 100 and be arranged so as to be spaced apart from each other. For example, the plurality of first plate parts 123 may be arranged in a matrix form. However, embodiments of the present disclosure are not limited thereto.

Referring to FIG. 3, the plurality of second plate parts 125 may be disposed on the non-display area NAA of the substrate 100. The plurality of second plate parts 125 may be disposed on the substrate 100 and be arranged so as to be spaced apart from each other. For example, the plurality of second plate parts 125 may be arranged to be spaced apart from each other along one direction of the substrate 100.

Referring to FIG. 4, the pixel PX including the plurality of sub-pixels may be disposed on the first plate part 123. Each sub-pixel may include a light-emitting element and a transistor configured to drive the light-emitting element. The light-emitting element may be embodied as a micro light emitting diode (micro LED). However, embodiments of the present disclosure are not limited thereto. For example, the light-emitting element may be embodied as an organic light-emitting element. Each of the plurality of sub-pixels may emit light in a wavelength range corresponding to one color among a plurality of colors different from each other. For example, the plurality of colors may include a red color, a green color, and a blue color. In another example, the plurality of colors may further include a white color.

Each of the plurality of sub-pixels may be connected to a plurality of connection wirings. For example, each of the plurality of sub-pixels may be electrically connected to the first connection wiring extending in the second direction and the second connection wiring extending in the first direction.

Referring to FIG. 5 and FIG. 6, one sub-pixel according to an embodiment of the present disclosure may include a transistor TR, a storage capacitor, and various wirings. The transistor TR may drive the light-emitting element ED, and the storage capacitor may store therein a voltage so that the light-emitting element ED may maintain the same state for one frame.

The flexible substrate 203 may be disposed on the substrate 110. The flexible substrate 203 may include a transparent plastic film or polyimide. However, embodiments of the present disclosure are not limited thereto.

A light shielding layer may be disposed on the flexible substrate 203. The light shielding layer may reduce a leakage current by preventing light from a position under the flexible substrate 203 from being incident to a semiconductor layer of the transistor TR. For example, the light shielding layer may be disposed under the semiconductor layer of the transistor TR which functions as a driving transistor.

A buffer layer including a single layer or multiple layers may be disposed between the flexible substrate 203 and the transistor TR. The buffer layer prevents impurities, oxygen, or moisture from diffusing toward the transistor TR, thereby preventing damage to the transistor TR, and protecting the transistor TR. For example, the buffer layer may be composed of a single layer or a multilayer of at least one of silicon oxide (SiOx) and silicon nitride (SiNx). However, embodiments of the present disclosure are not limited thereto.

The transistor TR may include the semiconductor layer, a gate insulating layer, a gate electrode, and source/drain electrodes. The gate insulating layer may be disposed between the semiconductor layer and the gate electrode. The semiconductor layer may be formed of an oxide semiconductor or silicon-based semiconductor material. For example, the semiconductor layer may include an oxide semiconductor material such as indium gallium-zinc-oxide (IGZO) or indium-zinc-oxide (IZO). However, embodiments of the present disclosure are not limited thereto. In another example, the semiconductor layer may include a polysilicon semiconductor material or a low-temperature polysilicon semiconductor material. However, embodiments of the present disclosure are not limited thereto.

The semiconductor layer may include an active area that overlaps the gate electrode in the vertical direction and constitutes a channel, and a source area and a drain area respectively disposed on both opposite sides of the active area. The source/drain electrodes may be electrically connected to the source area and the drain area of the semiconductor layer, respectively.

On the transistor TR, a passivation layer including an insulating material that protects the transistor TR and a planarization layer that planarizes a surface step caused by an underlying structure such as the transistor TR may be disposed. The planarization layer may be formed of an organic insulating material including a photoactive compound (PAC). However, embodiments of the present disclosure are not limited thereto. The planarization layer may have a multi-layer structure in which one or more organic insulating films are stacked. However, embodiments of the present disclosure are not limited thereto.

The light-emitting element ED may be electrically connected to the transistor TR. In one example, the light-emitting element ED may be embodied as a micro LED. However, embodiments of the present disclosure are not limited thereto.

The light-emitting element ED may include a nitride semiconductor structure and a connection electrode CE. The light-emitting element ED may include a lateral type nitride semiconductor structure, a vertical type nitride semiconductor structure, or a flip-chip type nitride semiconductor structure. However, embodiments of the present disclosure are not limited thereto.

The light-emitting element ED may be electrically connected to the transistor TR via the connection electrode CE. For example, the connection electrode CE may include a metal material. Various signals or voltages supplied via the transistor TR electrically connected to the connection electrode CE of the light-emitting element ED may be transmitted to the light-emitting element ED. For example, a voltage to drive the light-emitting element ED may be applied from the transistor TR thereto. Voltages of different levels may be applied to the light-emitting element ED via the connection electrode CE, so that the light-emitting element ED may emit light.

The sub-pixel including the transistor TR and the light-emitting element ED may include the second connection wiring 135 connected to a pad terminal 219 of the panel driver 127 of the second plate part 125 in FIG. 6. The second connection wiring 135 may be electrically connected to the connection electrode CE of the light-emitting element ED.

The panel driver 127 of the second plate part 125 may be connected to the pad terminal 219 by a TAB (Tape Automated Bonding) scheme. However, embodiments of the present disclosure are not limited thereto. The second connection wiring 135 may be disposed on the flexible substrate 203. Multiple layers formed of an insulating material under the light-emitting element ED disposed in the first plate part 123 may be disposed in the second plate part 125. The insulating layers disposed in the second plate part 125 may be formed in the same process as a process in which the first plate part 123 is formed. However, embodiments of the present disclosure are not limited thereto.

Referring to FIG. 5 and FIG. 6 together, the cover window 300 including the second cover member 340, the light-blocking pattern part 320, and the first cover member 310 may be disposed on the light-emitting element ED and the panel driver 127. The cover window 300 may further include an optical functional film layer 350 such as an anti-reflection film or an anti-glare layer disposed on the first cover member 310. The light-blocking pattern part 320 may be disposed to overlap the connection wiring 130 and the panel driver 127 and the pad terminal 219 disposed in the second plate part 125 so as to prevent the connection wiring 130 and the panel driver 127 and the pad terminal 219 from being visible to the viewer.

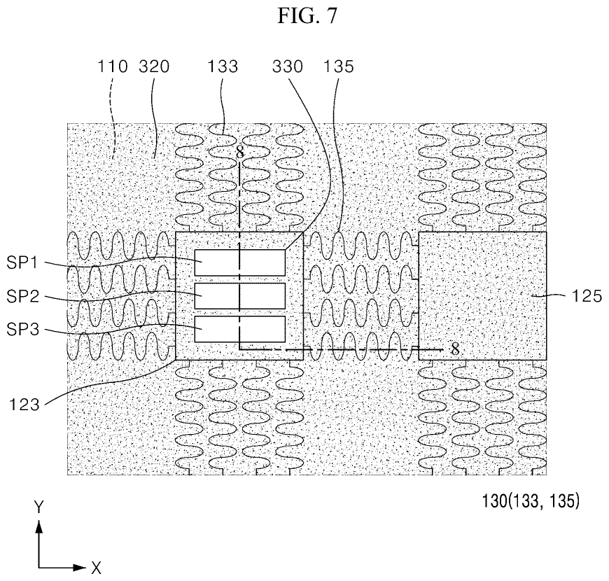

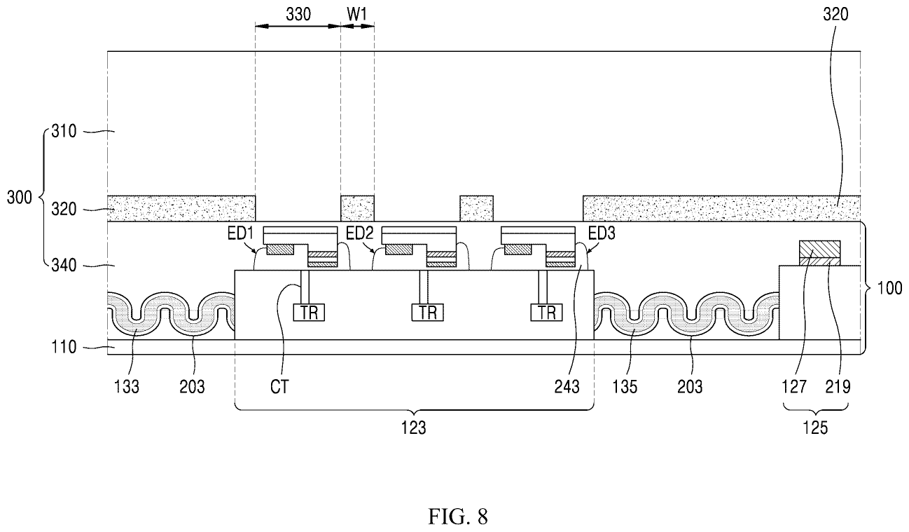

FIG. 7 and FIG. 8 illustrate a display apparatus according to an embodiment of the present disclosure. FIG. 8 is a cross-sectional view along a line 8-8 in FIG. 7 according to an embodiment of the present disclosure. In FIG. 7, for convenience of illustration, an area where the light-blocking pattern part 320 is formed is shown, and the first cover member 300 is not shown. FIG. 8 illustrates a flip-chip type light-emitting element ED for convenience of illustration. However, embodiments of the present disclosure are not limited thereto.

Referring to FIG. 7 and FIG. 8, the first plate part 123 and the second plate part 125 disposed on the display panel 100 may be spaced apart from each other along the X-axis direction as the first direction of the substrate 110. The plurality of sub-pixels (for example, the first sub-pixel SP1, the second sub-pixel SP2, and the third sub-pixel SP3, but not limited thereto) may be disposed in the first plate part 123. The plurality of sub-pixels may respectively emit light having different colors to an outside through the opening 330. In each of the plurality of sub-pixels, the light-emitting element ED and the circuit element including a transistor TR configured to drive the light-emitting element ED in FIG. 5 may be disposed. Each of the plurality of light-emitting elements (for example, a first light-emitting element ED1, a second light-emitting element ED2, and a third light-emitting element ED3, but not limited thereto) and each of a plurality of transistors TR may be electrically connected to each other via a respective contact electrode CT. The contact electrode CT may at least one source/drain electrode or a metal wiring for electrically connecting the light-emitting element ED and the transistor TR in FIG. 5 to each other.

The second plate part 125 may include the pad terminal 219 as shown in FIG. 6. The pad terminal 219 may be electrically connected to the panel driver 127 which transmits various signals to the plurality of sub-pixels.

The connection wiring 130 may include the second connection wiring 135 extending in the X-axis direction as the first direction, and the first connection wiring 133 extending in the Y-axis direction as the second direction. The first plate part 123 and the second plate part 125 may be electrically connected to each other via the second connection wiring 135.

The rear surface of each of the first connection wiring 133 and the second connection wiring 135 may be supported by the flexible substrate 203. When the flexible substrate 203 serves as a support member, the flexible substrate 230 may have the same shape as that of a combination of the first connection wiring 133 and the second connection wiring 135. However, embodiments of the present disclosure are not limited thereto. Each of the first and second connection wirings 133 and 135 may include a shape in which irregularities are continuously repeated or a concave-convex shape. However, embodiments of the present disclosure are not limited thereto. For example, each of the first and second connection wirings 133 and 135 may extend in a wave shape or a zigzag shape. However, embodiments of the present disclosure are not limited thereto.

The cover window 300 including the first cover member 310, the light-blocking pattern part 320, and the second cover member 340 may be disposed so as to be in contact with the display panel 100. The cover window 300 may have a thickness of 250 μm to 350 μm. However, embodiments of the present disclosure are not limited thereto. The first cover member 310 and the second cover member 340 of the cover window 300 may be formed of (or include) materials having different elastic modulus. The first cover member 310 may be formed of (or include) a material having an elastic modulus which does not exceed a maximum of 5 Mpa. The second cover member 340 may be formed of (or include) a material having a modulus of 1 MPa or less, which is lower than that of the first cover member 310. In this regard, the elastic modulus (or modulus of elasticity) may be a value representing a ratio of a strain of an object relative to a stress applied to the object.

For example, the first cover member 310 may be formed of (or include) an elastomer such as silicone rubber, or polydimethylsiloxane (PDMS) as a mixture of silicone and a curing agent. However, embodiments of the present disclosure are not limited thereto. The second cover member 340 may be formed of (or include) an optically cleared adhesive (OCA) or an optically cleared resin (OCR). However, embodiments of the present disclosure are not limited thereto.

The second cover member 340 of the cover window 300 may cover the plurality of light-emitting elements (for example, the first light-emitting element ED1, the second light-emitting element ED2, and the third light-emitting element ED3, but not limited thereto) the first connection wiring 133, and the second connection wiring 135 of the display panel 100.

The light-blocking pattern part 320 may be disposed between the first cover member 310 and the second cover member 340. The light-blocking pattern part 320 may cover an entire surface of the second cover member 340 except for the opening 330 through which light emitted from each of the plurality of light-emitting elements of each of the plurality of sub-pixels (for example, the first sub-pixel SP1, the second sub-pixel SP2, and the third sub-pixel SP3, but not limited thereto) exposed through the opening 330. For example, the light-blocking pattern part 320 may overlap one side edge (or a periphery of one portion) and the other side edge (or a periphery of the other portion) of each of the plurality of light-emitting elements. For example, the light-blocking pattern part 320 may overlap a side edge (or a periphery of one portion, for example, a periphery of a right portion as shown in FIG. 8) of the light-emitting element ED3 and the second connection wiring 135. The light-blocking pattern part 320 may have a thickness of 10 μm to 20 μm. However, embodiments of the present disclosure are not limited thereto.

A portion of the light-blocking pattern part 320 disposed in a boundary area between adjacent ones of the plurality of sub-pixels may have a first width W1. For example, a portion of the light-blocking pattern part 320 that overlaps one side edge (or a periphery of one portion) of one of adjacent ones of the plurality of light-emitting elements and the other side edge (or a periphery of the other portion) of the other one thereof may have the first width W1. The first width W1 of the light-blocking pattern part 320 may be sized such that the second connection wiring 135 as shown in FIG. 8 may not be visible to the viewer. For example, the first width W1 may be in a range of 1 μm to 3 μm and the light-blocking pattern part 320 may have an optical density (OD) value greater than 2. Accordingly, color mixing between light beams from the plurality of sub-pixels may be prevented.

In one example, the light-blocking pattern part 320 may include a film formed of a mixture of polydimethylsiloxane (PDMS) and an opaque pigment. The opaque pigment may be a black pigment. However, embodiments of the present disclosure are not limited thereto, and pigments of other colors may be used. For example, the stretchable display apparatus may be embodied on a wearable object such as a bag. In this case, for color matching between the display apparatus and the wearable object, the opaque pigment may have the same color as the background color of the wearable object.

Due to the nature of the stretchable display apparatus in which stretching or variation (or deformation) is repeated, the display panel 110 may have a structure in which the plurality of first plate parts 123 and the plurality of second plate parts 125 as rigid areas may be arranged so as to be spaced apart from each other while being disposed on the substrate 110 having softness. Further, the first plate part 123 and the second plate part 125 respectively disposed on the display area AA and the non-display area NAA of the display panel 100 (see FIG. 3) may be electrically connected to each other via the connection wiring 130. Additionally, the connection wiring 130 may be disposed in the soft area, such that an external force for stretching the display apparatus may be repeatedly applied to the connection wiring 130.

Since the plurality of first plate parts 123 and the plurality of second plate parts 125 as rigid areas are not stretched, the soft area where the connection wiring 130 is disposed may be stretched, such that the display panel 100 may be bendable or stretchable. To stretch the substrate 110 by, for example, about 20% from its original shape, the soft area where the connection wiring 130 is disposed should be stretched by, for example, about 40%. Accordingly, when the stretching or deformation (or variation) is repeated, the external force for stretching the display apparatus is repeatedly applied to the connection wiring 130, so that the connection wiring 130 may be deformed. 20% stretching or about 40% stretching from the original form does not limit embodiments of the present disclosure.

The connection wiring 130 may include a metal wiring formed of a material including copper (Cu), etc. However, embodiments of the present disclosure are not limited thereto. To prevent the connection wiring 130 from being visible to the viewer, a decoration area may be disposed using a bezel on an edge (or a periphery) of the display panel, or a polarizer may be disposed on an edge (or a periphery) of the display panel. However, both the polarizer and the bezel are formed of a material that may not be easily stretched. Thus, as the stretching operation is repeated, the deformed connection wiring may be recognized by the user, thereby deteriorating an immersion experience of the user into the screen. Furthermore, when the decoration area or the polarizer is present, an overall thickness of the display apparatus may become larger due to a multi-layered structure. Therefore, to construct the multilayer structure, the number of process steps necessarily increases. Thus, as the number of process steps increases, the possibility of defects occurring may increase.

According to an embodiment of the present disclosure, even when the stretching is repeated, the connection wiring, etc., may not be recognized by the user due to the presence of the light-blocking pattern part, and the overall thickness of the display apparatus may be reduced.

According to an embodiment of the present disclosure, a structure of the display apparatus may be slimmed by integrating the light-blocking pattern part that screens (or hides) the connection wiring disposed in the display area or the non-display area of the stretchable display apparatus with the cover window. Thus, a lightweight display apparatus may be realized. Furthermore, the cover window integrated with the light-blocking pattern part may be disposed on the display panel, thereby preventing the connection wiring from being visible to the user (or viewer) during the stretching operation or as the stretching operation is repeated.

Furthermore, due to the cover window integrated with the light-blocking pattern part, the polarizer that prevents external light from being reflected from the connection wiring disposed in the display area or the non-display area may be omitted, such that the structure of the display apparatus may be simplified.

According to embodiments of the present disclosure, the light-blocking pattern part may be integrated into the cover window. Thus, a decoration film that may prevent the connection wiring disposed in the non-display area or in an outer portion of the display panel from being visible to the user (or viewer) may be omitted, such that the structure of the display apparatus may be simplified. Accordingly, an overall thickness and an overall weight of the display apparatus may be reduced, thereby reducing production energy consumption of the display apparatus.

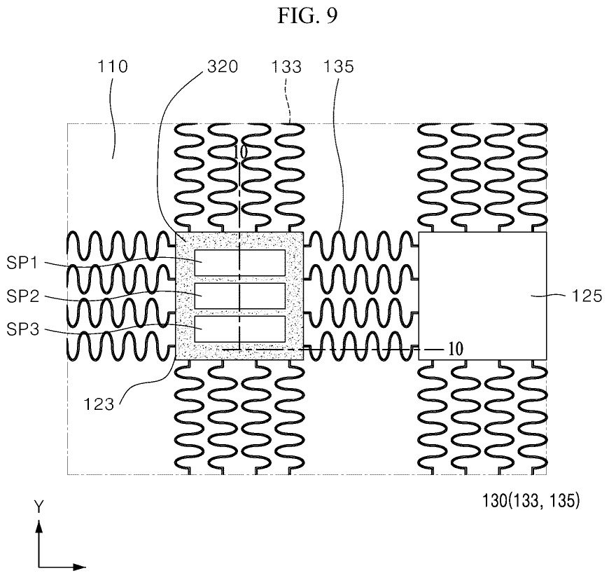

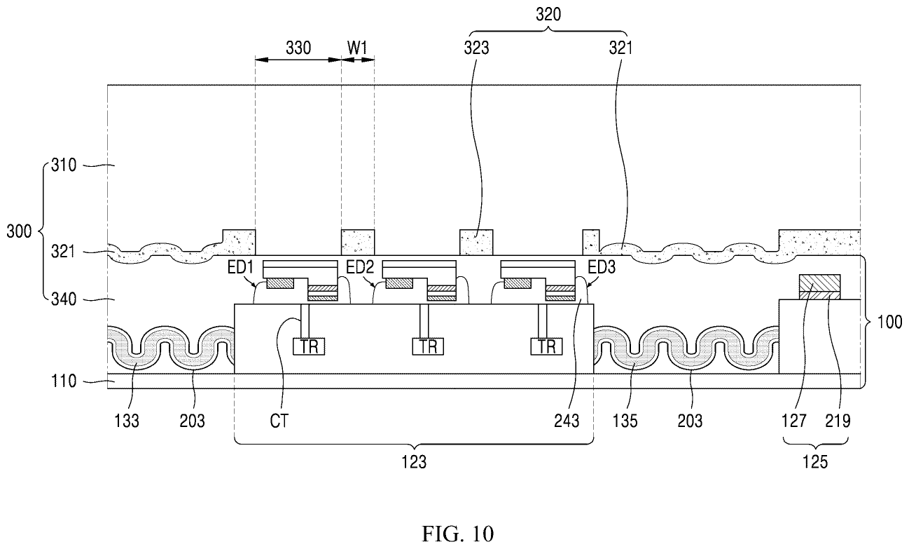

FIG. 9 and FIG. 10 illustrate a display apparatus according to another embodiment of the present disclosure. FIG. 10 is a cross-sectional view taken along a line 10-10 in FIG. 9 according to another embodiment of the present disclosure.

The display apparatus of FIG. 9 and FIG. 10 has substantially the same configuration as that of the display apparatus in FIG. 7 and FIG. 8 except for a location of the light-blocking pattern part. Thus, relevant elements in the display apparatus in FIG. 7 and FIG. 8 are referred to by like reference numerals, and repeated descriptions thereof are omitted or will be briefly given.

Referring to FIG. 9 and FIG. 10, the first plate part 123 and the second plate part 125 may be arranged so as to be spaced apart from each other along the X-axis direction as the first direction of the substrate 110 while being disposed on the display panel 100. A plurality of sub-pixels (for example, a first sub-pixel SP1, a second sub-pixel SP2, and a third sub-pixel SP3, but not limited thereto) may be disposed in the first plate part 123. The plurality of sub-pixels may respectively emit light having different colors to the outside through the opening 330. In each of the plurality of sub-pixels, the light-emitting element ED and the circuit element including the transistor TR configured to drive the light-emitting element ED may be disposed. Each of a plurality of light-emitting elements (for example, a first light-emitting element ED1, a second light-emitting element ED2, and a third light-emitting element ED3, but not limited thereto) and each of the plurality of transistors TR may be electrically connected to each other via a respective contact electrode CT. The contact electrode CT may include at least one metal wiring such as a source/drain electrode, a first connection electrode, or a second connection electrode.

The second plate part 125 may include the pad terminal 219 shown in FIG. 6, and the panel driver 127 (see FIG. 1) that transmits various signals to the plurality of sub-pixels. However, embodiments of the present disclosure are not limited thereto.

The connection wiring 130 may include the second connection wiring 135 extending in the X-axis direction as the first direction, and the first connection wiring 133 extending in the Y-axis direction as the second direction. The first plate part 123 and the second plate part 125 may be electrically connected to each other via the second connection wiring 135.

The rear surface of each of the first connection wiring 133 and the second connection wiring 135 may be supported by the flexible substrate 203. When the flexible substrate 203 serves as a support member, the flexible substrate 230 may have the same shape as that of a combination of the first connection wiring 133 and the second connection wiring 135. However, embodiments of the present disclosure are not limited thereto. Each of the first and second connection wirings 133 and 135 may include a shape in which irregularities are continuously repeated or a concave-convex shape. However, embodiments of the present disclosure are not limited thereto. For example, each of the first and second connection wirings 133 and 135 may extend in a wave shape or a zigzag shape. However, embodiments of the present disclosure are not limited thereto.

When the display panel 100 is stretched, the first connection pattern 133 and the second connection wiring 135 may be deformed. For example, when an external force is applied to the display panel 100 such that the display panel is stretched, the first connection pattern 133 and the second connection wiring 135 may be stretched such that a curved portion thereof becomes flat or the curvature thereof is decreased. Accordingly, the first connection pattern 133 and the second connection wiring 135 may properly perform the function of supplying the signal as the stretching operation is repeated.

The cover window 300 including the first cover member 310, the light-blocking pattern part 320, and the second cover member 340 may be disposed on the display panel 100. The second cover member 340 of the cover window 300 may cover the plurality of light-emitting elements, the first connection wiring 133, and the second connection wiring 135 of the display panel 100.

The light-blocking pattern part 320 may include a first pattern part 321 and a second pattern part 323.

The first pattern part 321 may have a shape corresponding to (for example, the same or similar shape as) that of each of the first connection wiring 133 and the second connection wiring 135. Embodiments of the present disclosure are not limited thereto. For example, the first pattern part 321 may have a shape in which irregularities are continuously repeated or a concave-convex shape or may have a wave shape or a zigzag shape. However, embodiments of the present disclosure are not limited thereto. Accordingly, only the first pattern part 321 of the light-blocking pattern part 320 may be selectively disposed to overlap the first connection wiring 133 and the second connection wiring 135. Additionally, an area of the substrate 110 having a transparent material except for an area overlapping with the first pattern part 321 may be exposed. Accordingly, a transparent display apparatus may be implemented.

The second pattern part 323 may have a first width W1. The second pattern part 323 may be disposed in a boundary area between adjacent ones of the plurality of sub-pixels excluding the opening 330 through which light is emitted. Accordingly, the second pattern part 323 may prevent color mixing between light beams emitted from adjacent ones of the plurality of sub-pixels.

The first pattern part 321 and the second pattern part 323 of the light-blocking pattern part 320 may be formed by screen-coating having a material on an entire surface of the substrate 110, and then performing an exposure and development process of selectively removing the coated material only in an area corresponding to the openings 330 of each of the plurality of sub-pixels. However, embodiments of the present disclosure are not limited thereto.

According to embodiments of the present disclosure, the light-blocking pattern part 320 may be disposed on an entire surface of the display panel 100 to prevent the connection wiring including a metal from being visible to the viewer or user. For example, or as an alternative, the light-blocking pattern part 320 may be selectively disposed only in an area where the circuit wirings including the connection wiring that may be visible to the viewer or user is disposed.

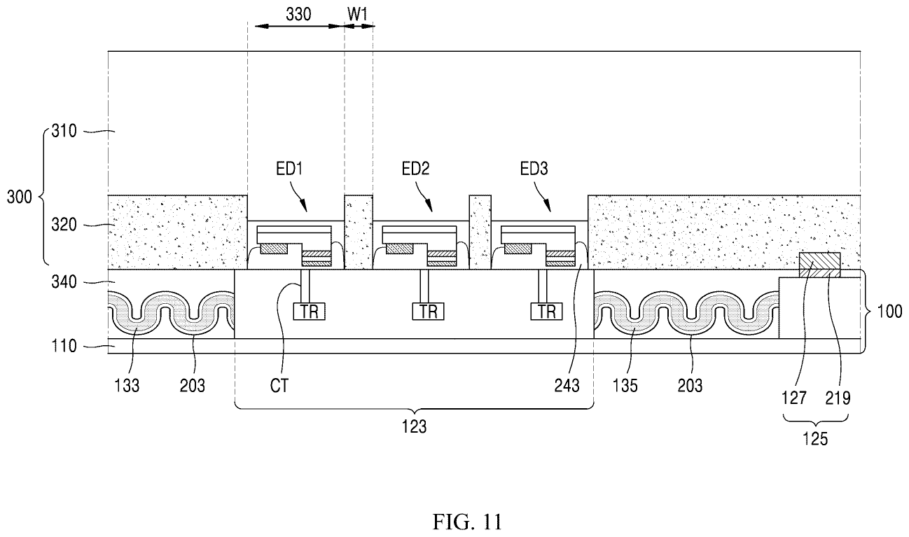

FIG. 11 illustrates a display apparatus according to another embodiment of the present disclosure. The display apparatus of FIG. 11 has substantially the same configuration as that of the display apparatus in FIG. 7 and FIG. 8 except for a location of the light-blocking pattern part. Thus, relevant elements in the display apparatus in FIG. 7 and FIG. 8 are referred to by like reference numerals, and repeated descriptions are omitted or will be briefly given.

Referring to FIG. 11, the plurality of first plate parts 123 and the plurality of second plate parts 125 may be disposed on the substrate 110. Adjacent first plate parts 123 may be electrically connected to each other via the first connection wiring 133 and the second connection wiring 135. The first plate part 123 and the second plate part 125 may be electrically connected to each other via the second connection wiring 135. Adjacent second plate parts 125 may be electrically connected to each other via the first connection wiring 133.

The plurality of sub-pixels such as the first sub-pixel SP1, the second sub-pixel SP2, and the third sub-pixel SP3 may be disposed in the first plate part 123. The plurality of sub-pixels such as the first sub-pixel SP1, the second sub-pixel SP2, and the third sub-pixel SP3 (see FIG. 7) each including a respective one of the plurality of light-emitting elements such as the first light-emitting element ED1, the second light-emitting element ED2, and the third light-emitting element ED3 may emit light having different colors to the outside.

The cover window 300 may be disposed so as to be in contact with the display panel 100. The second cover member 340 of the cover window 300 may cover the first connection wiring 133 and the second connection wiring 135. The light-blocking pattern part 320 having an opening 330 defined therein may be disposed on the second cover member 340. Light emitted from each of the plurality of light-emitting elements may be emitted through each opening 330.

The light-blocking pattern part 320 may be disposed to cover the boundary area between adjacent ones of the plurality of sub-pixels, and the first connection wiring 133 and the second connection wiring 135. The light-blocking pattern part 320 may be formed by applying a material constituting the light-blocking pattern part 320 on the boundary area between adjacent ones of the plurality of sub-pixels, and on an upper surface of each of the first connection wiring 133 and the second connection wiring 135 by an inkjet printing.

Different colors of light beams respectively emitted from adjacent ones of the plurality of light-emitting elements may be prevented from being mixed with each other due to the light-blocking pattern part 320 covering the boundary area between adjacent ones of the plurality of sub-pixels. The first cover member 310 of the cover window 300 may be disposed on the light-blocking pattern part 320. The first cover member 310 may cover the plurality of light-emitting elements.

According to an embodiment of the present disclosure, the light-blocking pattern part 320 covering the boundary area between adjacent ones of the plurality of sub-pixels, the first connection wiring 133, and the second connection wiring 135 may be disposed on the first plate part 123 and the second plate part 125.

In an embodiment of the present disclosure, as the light-blocking pattern part 320 may be disposed to fill a space between adjacent ones of the plurality of light-emitting elements. Thus, different colors of light respectively emitted from adjacent ones of the plurality of light-emitting elements may be prevented from being mixed with each other.

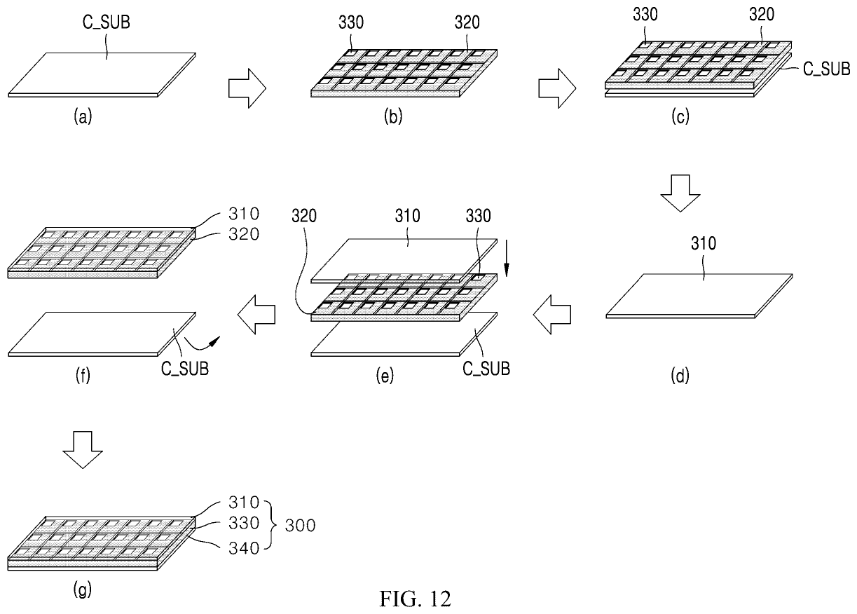

FIG. 12 illustrates a method for manufacturing a display apparatus in accordance with an embodiment of the present disclosure.

Referring to FIG. 12, a carrier substrate C_SUB is provided at a step (a). The carrier substrate C_SUB may include a PET (polyethylene terephthalate) film whose surface has been treated so as to be free of an adhesive force. The carrier substrate C-SUB may be configured to fix the light-blocking pattern part to be formed later when transferring the light-blocking pattern part. Next, the light-blocking pattern part 320 including the opening 330 may be formed at a step (b), and the light-blocking pattern part 320 may be disposed on the carrier substrate C-SUB at a step (c).

In one embodiment of the present disclosure, the light-blocking pattern part 320 may be formed by printing a material on the carrier substrate C-SUB. The opening 330 defined in the light-blocking pattern part 320 may be an area where each of the plurality of light-emitting elements is disposed. Light emitted from the light-emitting element may be emitted to the outside through the opening 330. The light-blocking pattern part 320 may be formed by patterning and curing a coating solution obtained by cross-linking of a plurality of surface-treated black particles and a silicone solution with each other, and description thereof will be provided later with reference to FIGS. 13 to 15.

Referring to FIG. 12, the first cover member 310 is provided at a step (d). The first cover member 310 may include an elastomer such as polydimethylsiloxane (PDMS) as a mixture of silicone and a curing agent. However, embodiments of the present disclosure are not limited thereto. Next, the first cover member 310 and the light-blocking pattern part 320 are bonded to each other at a step (e). The carrier substrate C_SUB is removed from the light-blocking pattern part 320 at a step (f). The second cover member 340 may be disposed under the light-blocking pattern part 320 to form the cover window including the second cover member 340, the light-blocking pattern part 320, and the first cover member 310. Then, the cover window formed in this way may be bonded or attached to the display panel, and a display apparatus may be manufactured.

The light-blocking pattern part 320 in the cover window 300 may include a film formed of a mixture of polydimethylsiloxane (PDMS) and an opaque pigment. In one example, the opaque pigment may be a black pigment. To prevent the metal wiring from being visible to the viewer, the pigment used in the light-blocking pattern part 320 may include carbon black pigment or titanium black pigment. However, embodiments of the present disclosure are not limited thereto.

FIGS. 13 to 15 illustrate a way of forming a light-blocking pattern part according to embodiments of the present disclosure.

Referring to FIG. 13, a plurality of black particles 405 may be uniformly dispersed in a silicone solution 400 to prepare a printing solution 410, and the printing solution 410 may be coated on the substrate 110 including polydimethylsiloxane (PDMS) to form the light-blocking pattern part. In this case, the plurality of black particles 405 are only dispersed in the silicone solution 400 but are not cross-linked with the silicone solution 400. For example, it may be difficult to print the opaque pigment on the substrate 110 including polydimethylsiloxane (PDMS) due to decrease in the surface energy of silicon which constitutes polydimethylsiloxane (PDMS).

Accordingly, the light-blocking pattern part formed of the printing solution in which the black particles 405 are dispersed in the silicone solution 400 may be peeled off from the surface of the substrate 110 when an external force is applied to the substrate as indicated by the arrow such that the substrate 110 is repeatedly stretched. When the light-blocking pattern part is peeled off from the surface of the substrate 110 to create a gap, the light reflected from the connection wiring or the metal wiring is visible to the viewer through the gap.

Furthermore, wrinkles occur in areas where the plurality of black particles 405 dispersed in the printing solution 410 are unevenly gathered at specific locations, such that the light reflected from the connection wiring or the metal wiring is visible to the viewer in an area in which the black particles are absent or gathered at a lower concentration.

The substrate 110 may be bent or stretched by bending or stretching an area where the connection wiring 130 is located under the light-blocking pattern part. The rigid area that is not stretched, including the first plate part 123 and the second plate part 125, may occupy 50% of a total area of the substrate 110. The stretching does not occur in the rigid area. Thus, as an example, the substrate 110 should be stretched by about 40% in the soft area where the connection wiring 130 is disposed such that an entire area of the substrate 110 may be stretched by about 20% from its original shape. Accordingly, when the substrate 100 is repeatedly stretched, the external force is repeatedly applied to the connection wiring 130, which may cause deformation of the connection wiring 130. Accordingly, it is necessary to prevent the connection wiring that has been deformed due to the repeated stretching operations from being visible or recognized by the viewer. However, the printing solution in which the black particles 405 are uniformly dispersed in the silicone solution 400 may prevent the light from transmitting therethrough before the substrate 110 is stretched, but when the substrate 110 is stretched by about 40% to create a dispersion force of the black particles 405 dispersed in the printing solution 410, the connection wiring disposed under the light-blocking pattern part may be visible or recognized by the user due to the dispersion force of the black particles 405 dispersed in the printing solution 410. For example, a difference between transmittances of the printing solution 410 in which the black particles 405 are dispersed in the silicone solution 400 before and after stretching is large, thereby making it difficult to compensate for the deformation of the connection wiring due to the stretching. Accordingly, when the substrate is repeatedly stretched, it may be difficult to prevent the connection wiring from being visible to the viewer.

The light-blocking pattern part according to embodiments of the present disclosure may be easily formed or coated on the substrate 110 by a coating solution obtained by cross-linking of the plurality of black particles and the silicone solution to each other, and no peeling phenomenon thereof occurs, thereby preventing the connection wiring from being visible or recognized by the viewer.

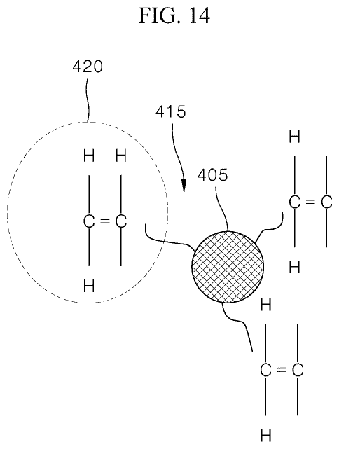

Referring to FIG. 14, surface-treated black particles 415 may be prepared to facilitate the cross-linking between the silicone solution and the black particles. The surface-treated black particles 415 may be formed by performing surface treatment on black particles 405 formed of nano black pigment particles 405 using a vinyl group precursor. The nano black pigment particles 405 may have a vinyl group 420 as a functional group that may be involved in a silicon (or silicone) polymerization reaction. A content of the vinyl group 420 may be adjusted such that 3 to 6 vinyl groups bind to the surface of each of the nano black pigment particles 405. However, embodiments of the present disclosure are not limited thereto.

When one or two vinyl groups 420 or more than 6 vinyl groups 420 bind to the surface of the nano black pigment particle 405, the bond may become stronger or weaker, which may adversely affect the stretching ability of the silicon (or silicone). Accordingly, the effect of preventing the wrinkles from occurring or preventing the connection wiring from being visible to the viewer may be reduced. For this reasons, three to six vinyl groups 420 may bind to the surface of each of the nano black pigment particles.

To form the printing solution using the surface-treated black particles 415, a silicone rubber solution as a first solution is prepared, and then prepare a second solution in which the surface-treated black particles 415 are dispersed in the silicone rubber solution. The surface-treated black particles 415 dispersed in the silicone solution of the second solution may be contained at a content in a range of 10% to 30% (for example, by weight percentage) of the silicone solution (in other words, the surface-treated black particles 415 dispersed in the silicone solution has a content in a range of 10% to 30% of the silicone solution). However, embodiments of the present disclosure are not limited thereto. Then, the second solution is stirred, and then a degassing process is performed thereon for 1 hour to remove air bubbles therefrom, thereby producing the coating solution for forming the light-blocking pattern part.

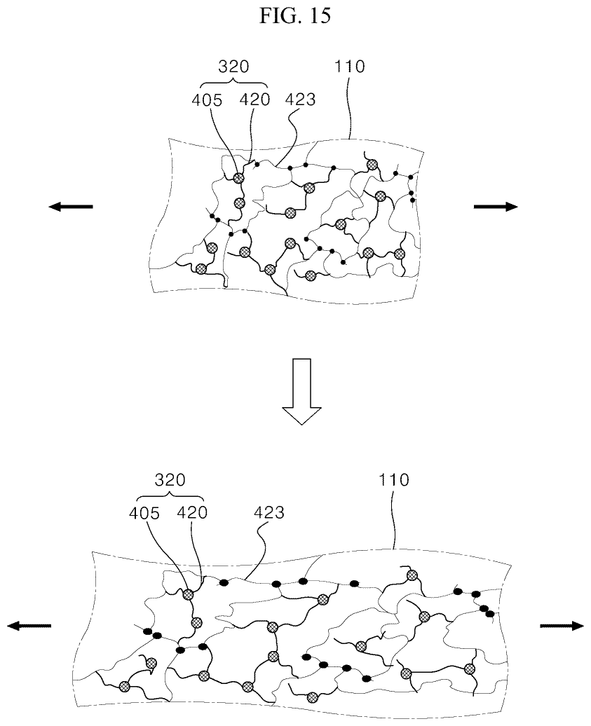

The coating solution may be coated on the substrate 110 and cured. The curing may utilize heat and/or ultraviolet (UV) light. As shown in FIG. 15, the binding energy may be increased by cross-linking between the vinyl groups 420 of the surface-treated black particles 415 and the molecule 423 of the silicone rubber. The molecule 423 of the silicone rubber may increase stretching characteristics because chains of the molecule 423 of the silicone rubber do not tangle (or bind) with each other. Accordingly, even when a force is applied to the light-blocking pattern part 320 in various directions as indicated by arrows, or the substrate 110 is repeatedly stretched, the light-blocking pattern part 320 formed by the coating solution in which the surface-treated black particles 415 and the silicone solution are cross-linked to each other may be prevented from peeling off from the surface of the substrate 110. Accordingly, even when the substrate 110 is stretched by about 40%, the connection wiring or the metal wiring may be still covered with the light-blocking pattern part 320, thereby preventing the connection wiring or the metal wiring from being visible to the viewer. According to embodiments of the present disclosure, the light-blocking pattern part is provided in the deformable or variable display apparatus with an elongation of 5% to 40% or an elongation of 40% or more. Thus, the deformable or variable display apparatus that may reduce visibility of reflected light may be provided.

The optical density (OD) value of the light-blocking pattern part 320 may be in a range from 1 to 3. To have the optical density (OD) value in the range of 1 to 3, a size of each of the surface-treated black particles 415 may be adjusted to be in a range of about 200 nm to 500 nm. When each of the surface-treated black particles 415 has a size of 100 nm or less, the optical density (OD) value may be out of range of 1 to 3, which may reduce the effect of preventing the connection wiring from being visible to the viewer. Furthermore, a thickness of the light-blocking pattern part 320 may be 5 μm or less. However, embodiments of the present disclosure are not limited thereto.

Based on a position where the light-blocking pattern part 320 is disposed, the optical density (OD) value may vary. For example, in a non-pixel area, the optical density (OD) value may have a value greater than 2.0. In this case, the area where the light-blocking pattern part 320 may be disposed may have a transmittance of about 10% or less. To maintain the optical density (OD) value to be greater than 2.0 in the non-pixel area so that the light-blocking pattern part 320 has a transmittance of about 10% or less, the content of surface-treated black particles 415 in the silicone solution should be adjusted. For example, the surface-treated black particles 415 may be contained at a content of 15% or more of the silicone solution. When the surface-treated black particles 415 are contained at a content of 15% of the silicone solution, the optical density (OD) value may be 2.1 and the transmittance may be about 7.5%. Furthermore, when the surface-treated black particles 415 are contained at a content of 20% of the silicone solution, the optical density (OD) value may be 2.9 and the transmittance may be about 1.5%. For example, as the content of the surface-treated black particles 415 in the silicone solution increases, a transmittance of the display apparatus may decrease. When the content of surface-treated black particles 415 in the silicone solution exceeds 30%, the optical density (OD) value may be out of range of 1 to 3, which may reduce the effect of preventing the connection wiring from being visible or recognized by the viewer. For example, when the content of the surface-treated black particles 415 in the silicone solution exceeds 30%, it becomes difficult to uniformly disperse the surface-treated black particles 415 in the silicone solution, and rather, the surface-treated black particles 415 may agglomerate with each other. Then, since the black particles 415 are not uniformly dispersed in the silicone solution, the area where the optical density (OD) value is out of range of 1 to 3 may occur, thereby causing a problem of deterioration of optical properties. The non-pixel area may be an area that is not substantially stretched, and may be a bezel area in the non-display area NAA surrounding the display area AA.

However, in a pixel area and a transmission area, the optical density (OD) value may be 1.0 or less. In this case, the area where the light-blocking pattern 320 may be disposed may have a transmittance of about 40% to 55%. The pixel area may include the boundary area between adjacent ones of the plurality of sub-pixels such as a first sub-pixel SP1, a second sub-pixel SP2, and a third sub-pixel SP3 (see FIG. 4) and the area where the connection wiring 130 is disposed.

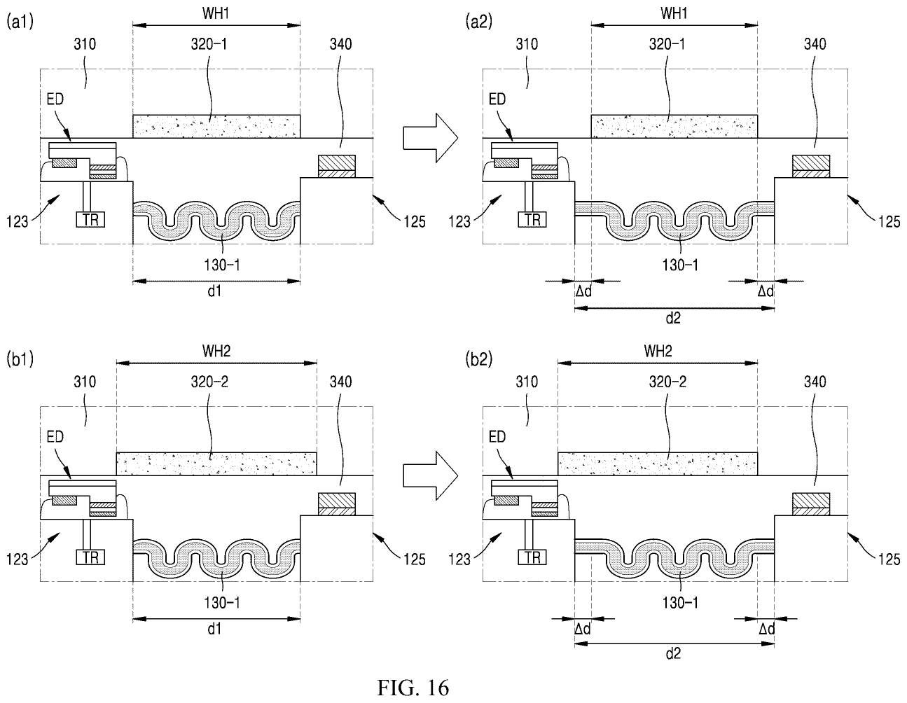

FIG. 16 illustrates a light-blocking pattern part according to an embodiment of the present disclosure.

Referring to FIG. 16, to electrically connect the first plate part 123 in which the light-emitting element ED of each sub-pixel is disposed and the second plate part 125 in which the panel driver 127 is disposed to each other, a connection wiring 130-1 may be disposed between the first plate part 123 and the second plate part 125.

The first plate part 123 and the second plate part 125 may be covered with the cover window including the first cover member 310, light-blocking pattern parts, and the second cover member 340. In this regard, the light-blocking pattern parts may include a first light-blocking pattern part 320-1 having a first width WH1 and a second light-blocking pattern part 320-2 having a second width WH2. The second width WH2 of the second light-blocking pattern part 320-2 may be larger than the first width WH1 of the first light-blocking pattern part 320-1. Accordingly, an area in which the second light-blocking pattern part 320-2 overlaps an edge (or a periphery) of the first plate part 123 and an edge (or a periphery) of the second plate part 125 may be larger than an area in which the first light-blocking pattern part 320-1 overlaps an edge (or a periphery) of the first plate part 123 and an edge (or a periphery) of the second plate part 125.

The first cover member 310 and the second cover member 340 constituting the cover window 300 may have different elastic modulus. For example, the elastic modulus of the first cover member 310 may be maintained not to exceed a maximum of 5 MPa to protect the display panel and minimize the hysteresis. The elastic modulus of the second cover member 340 of the cover window 300 may be maintained at 1 MPa or less which is lower than that of the first cover member 310, thereby maintaining flexibility. Thus, when the display panel is stretched, the hysteresis may be minimized to facilitate the deformation of the connection wiring 130-1 and restoration thereof to its original form.

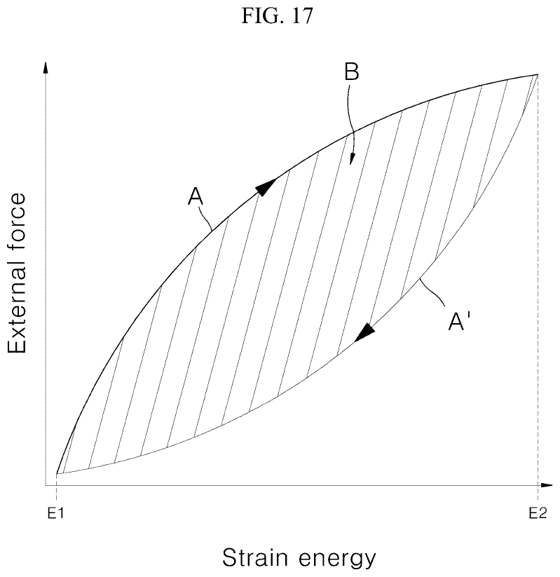

FIG. 17 illustrates an example of hysteresis characteristics according to some embodiments of the present disclosure.

In FIG. 17, a horizontal axis represents a strain (or tensile) energy, and a vertical axis represents an external force. Hysteresis is a phenomenon in which a material does not return to its original state (or value) but changes to a different state (or value) therefrom when the material is deformed periodically or within a range in response to a specific external stimulus. Referring to FIG. 17, a thin film, a pattern, or a wiring is stretched by applying the force thereto and then is not restored to its original state by a deviation when the force is removed therefrom. This may refer to the hysteresis which may be expressed as a curve indicating the deviation as shown in FIG. 17. The hysteresis may be a difference B between a first area A of the force corresponding to a range from a first point (as a starting point) E1 to a second point (as an ending point) E2 of the strain energy due to the deformation that occurs when the force is applied to the thin film, pattern, or wiring, etc., and a second area A′ of the force corresponding to a range from a second point (as a starting point) E2 to a first point (as an ending point) E1 of the strain energy due to the deformation that occurs when the force applied to the thin film, pattern, or wiring, etc., is removed. As the hysteresis as the difference B between the first area A and the second area A′ is smaller, the plastic deformation becomes smaller, such that the thin film, pattern, or wiring has good characteristics at which the thin film, pattern, or wiring can be restored to its original form. However, as the hysteresis as the difference B between the first area A and the second area A′ increases, the plastic deformation becomes greater, such that the thin film, pattern, or wiring has bad characteristics at which the thin film, pattern, or wiring cannot be restored to its original form. Accordingly, as the hysteresis of each of the first cover member 310 and the second cover member 340 is minimized, the connection wiring may be easily deformed and restored to its original form during the stretching operation of the display panel.

The elastic modulus (modulus of elasticity) may be a value representing a ratio of the stain of the material relative to the stress applied to the material. When the elastic modulus is relatively high, the hardness (or the rigidity) may be relatively high. Furthermore, when the elastic modulus is relatively low, flexibility may be relatively high.

When the display panel is stretched, the first cover member 310 and the second cover member 340 which have different elastic modulus may have different elongations at the first cover member 310 and the second cover member 340, respectively. For example, the second cover member 340 with a relatively low elastic modulus may be stretched more easily, and the first cover member 310 with a relatively high elastic modulus may have a smaller stretched length than that of the second cover member 340.

Accordingly, when the connection wiring 130-1 that electrically connects the first plate part 123 and the second plate part 125 to each other is not sufficiently covered with the light-blocking pattern part, the connection wiring 130-1 may be visible to the viewer after the stretching operation.

For example, when the substrate 110 is stretched by about 20% from its original shape, the connection wiring 130 may be stretched, but the first plate part 123 and the second plate part 125 as the rigid areas may not be stretched. Accordingly, to stretch the substrate 110 by about 20% from its original shape, the connection wiring 130 disposed between the first plate part 123 and the second plate part 125 should be stretched by about 40%. Therefore, when the connection wiring 130 is not covered with the light-blocking pattern part 320, the connection wiring may be exposed to the outside. The maximum amount of deformation at which the display panel may be stretched without damaging the substrate 110 may be about 20% from its original shape in the up, down, left, right, or diagonal direction. However, embodiments of the present disclosure are not limited thereto.

For example, referring to a part (a1) and a part (a2) in FIG. 16, the first light-blocking pattern part 320-1 having the first width WH1 may be disposed under the first cover member 310, and the connection wiring 130-1 may be disposed to overlap the first light-blocking pattern part 320-1 in the up and down direction (or the vertical direction). When the stretching operation is performed, a length of the connection wiring 130-1 may be increased from a first length d1 to a second length d2 by a length of Δd×2. However, the first light-blocking pattern part 320-1 having the first width WH1 may not cover the first light-blocking pattern part 320-1 in an area between each of the first plate part 123 and the second plate part 125 and the connection wiring 130-1 resulted by the increased length of Δd×2. This area not covered by the first light-blocking pattern part 320-1 may be referred to as a gap. Thus, the connection wiring 130-1 may be visible to the viewer through the gap that is not covered by the first light-blocking pattern part 320-1. For example, the elongations of the first and second cover members 310 and 340 having different elastic modulus are different from each other, and the second cover member 340 having a lower elastic modulus than that of the first cover member 310 is more easily stretched. Thus, the gap may occur between the rigid area and the soft area. As a result, the visibility of the connection wiring 130-1 of the circuit area may be increased.

Accordingly, referring to a part (b1) and a part (b2) of FIG. 16 according to an embodiment of the present disclosure, in consideration of the difference between the elongations of the first cover member 310 and the second cover member 340, the second light-blocking pattern part 320-2 may have the second width WH2. The second width WH2 may be larger than the first width WH1. The second light-blocking pattern part 320-2 having the second width WH2 may have an area overlapping with a respective edge (or periphery) of the first plate part 123 and the second plate part 125 to be increased than the first light-blocking pattern part 320-1.

When the stretching operation is performed, a length of the connection wiring 130-1 may be increased from a first length d1 to a second length d2 by a length of Δd×2. The second light-blocking pattern part 320-2 may have an area overlapping with a respective edge (or periphery) of the first plate part 123 and the second plate part 125 to be increased than the first light-blocking pattern part 320-1. Thus, even when the length of the connection wiring 130-1 is increased during the stretching operation, the connection wiring 130-1 may be covered by the second light-blocking pattern part 320-2. Accordingly, the connection wiring 130-1 may not be visible to the viewer during the stretching operation. According to embodiments of the present disclosure, even when the first and second cover members 310 and 340 are stretched to the same length, the circuit area may be screened by the light-blocking pattern part, such that the connection wiring 130-1 of the circuit area may not be visible to the user.

According to embodiments of the present disclosure, the cover window integrated with the light-blocking pattern part that screens the connection wiring disposed in the display area of the stretchable display apparatus or in the non-display area thereof may be disposed on the display panel, thereby preventing the connection wiring from being recognized by the user when the stretching operation is performed, or the stretching operation is repeated.

According to embodiments of the present disclosure, the cover window integrated with the light-blocking pattern part may be used, instead of the cover window including the multi-layer structure of the polarizer, the decorative film, and a black matrix. Thus, an overall thickness of the display apparatus may be reduced.

The light-blocking pattern part according to embodiments of the present disclosure may have an increased overlapping area with a respective periphery of the first plate part and the second plate part. Thus, the connection wiring may be prevented from being visible to a viewer even when the length of the connection wiring is increased in the stretching operation.

According to embodiments of the present disclosure, the polarizer may be removed or omitted, but the light-blocking pattern part which may be stretched by more than 40% may be disposed. Thus, a display apparatus that may be stretched by more than 40% may be realized.

A display apparatus according to various embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, deformable apparatuses, electronic notebooks, e-books, portable multimedia players (PMP), personal digital assistants (PDA), MP3 players, mobile medical apparatuses, desktop PCs, laptop PCs, netbook computers, workstations, navigations, vehicle navigations, vehicle display apparatuses, vehicle apparatuses, theater apparatuses, theater display apparatuses, televisions, wallpaper apparatuses, signage apparatuses, game apparatuses, laptops, monitors, cameras, camcorders, and home appliances, etc.

A display apparatus according to various embodiments of the present disclosure may be described as follows.

A display apparatus according to various embodiments of the present disclosure may comprise a substrate including a display area and a non-display area adjacent to the display area, the substrate being variable, a plurality of connection wirings disposed on the substrate, a cover window disposed at least over the plurality of connection wirings, and a light-blocking pattern part included in the cover window. The substrate may be pliable, rollable, flexible, foldable, stretchable, bendable, wearable, or the like.

According to various embodiments of the present disclosure, the plurality of first plate parts may be arranged to be spaced apart from each other and configured to be relatively more rigid than the substrate, and the plurality of second plate parts may be arranged to be spaced apart from each other and configured to be relatively more rigid than the substrate.

According to various embodiments of the present disclosure, the cover window may further include a first cover member, and a second cover member. The light-blocking pattern part may be between the first cover member and the second member.

According to various embodiments of the present disclosure, a first cover member disposed over the light-blocking pattern part (for example, on an upper surface of the light-blocking pattern part). For example, a second cover member disposed under the light-blocking pattern part (for example, on a lower surface of the light-blocking pattern part).

According to various embodiments of the present disclosure, the second cover member may cover the plurality of first plate parts, the plurality of second plate parts, and the plurality of connection wirings.

According to various embodiments of the present disclosure, the first cover member, the light-blocking pattern part, and the second cover member may be integrated with each other.

According to various embodiments of the present disclosure, the first cover member and the second cover member may have different elastic modulus.

According to various embodiments of the present disclosure, the elastic modulus of the first cover member may be greater than the elastic modulus of the second cover member.

According to various embodiments of the present disclosure, the first cover member may have an elastic modulus which does not exceed a maximum of 5 MPa, and the second cover member may have an elastic modulus of 1 MPa or less.

According to various embodiments of the present disclosure, the first cover member may include an elastomer, the second cover member may include an optically cleared adhesive or an optically cleared resin, and the light-blocking pattern part may include an opaque material.

According to various embodiments of the present disclosure, the light-blocking pattern part may be disposed in a boundary area between adjacent ones of the plurality of sub-pixels and disposed on the second cover member.

According to various embodiments of the present disclosure, the light-blocking pattern part may be disposed on an entire surface of the second cover member.

According to various embodiments of the present disclosure, the light-blocking pattern part may have an opening through the light-blocking pattern part, the opening may be a light emitting area where light emitted from a light-emitting element disposed in one of the plurality of sub-pixels is emitted, and the light-blocking pattern part may be disposed on an entire surface of the second cover member excluding the opening.

According to various embodiments of the present disclosure, the plurality of connection wirings may include a first connection wiring configured to be electrically connected to adjacent ones of the first plate parts to each other and be electrically connected to adjacent ones of the second plate parts to each other, respectively, and a second connection wiring configured to be electrically connected to the first plate part and the second plate part adjacent to each other.

According to various embodiments of the present disclosure, the plurality of connection wirings may include a first connection wiring extending in a second direction and configured to electrically connect adjacent ones of the plurality of first plate parts to each other and electrically connect adjacent ones of the plurality of second plate parts to each other, respectively, and a second connection wiring extending in a first direction different from the first direction and configured to electrically connect adjacent ones of the plurality of first plate parts to each other and electrical connected the first plate part and the second plate part adjacent to each other, respectively.

According to various embodiments of the present disclosure, a rear surface of each of the first connection wiring and the second connection wiring may be supported by a flexible substrate.

According to various embodiments of the present disclosure, the light-blocking pattern part may be disposed over at least an area corresponding to the first connection wiring and the second connection wiring.

According to various embodiments of the present disclosure, each of the plurality of connection wirings may include a shape in which irregularities are continuously repeated or a concave-convex shape.

According to various embodiments of the present disclosure, each of the plurality of connection wirings may extend in a wave shape or a zigzag shape.

According to various embodiments of the present disclosure, the cover window further may include an optical functional film layer disposed on the first cover member.

According to various embodiments of the present disclosure, the cover window may have a thickness of 250 μm to 350 μm and/or the light-blocking pattern part may have a thickness of 10 μm to 20 μm.

According to various embodiments of the present disclosure, the display apparatus may further comprise a plurality of light-emitting elements respectively disposed in the plurality of sub-pixels and spaced apart from each other. A portion of the light-blocking pattern part may be disposed between adjacent ones of the plurality of light-emitting elements.

According to various embodiments of the present disclosure, the portion of the light-blocking pattern part disposed between adjacent ones of the plurality of light-emitting elements has a first width in a range of 1 μm to 3 μm.

According to various embodiments of the present disclosure, the light-blocking pattern part may include a film formed of a mixture of polydimethylsiloxane and an opaque pigment.

According to various embodiments of the present disclosure, the light-blocking pattern part may include a first pattern part and a second pattern part, the first pattern part may be disposed to overlap with the first connection wiring and the second connection wiring, and may have a shape corresponding to that of each of the first connection wiring and the second connection wiring, the second pattern part may be disposed in a boundary area between adjacent ones of the plurality of sub-pixels.

According to various embodiments of the present disclosure, the light-blocking pattern part covering a boundary area between adjacent ones of the plurality of sub-pixels, the first connection wiring, and the second connection wiring may be disposed on the first plate part and the second plate part.

According to various embodiments of the present disclosure, the light-blocking pattern part is disposed to fill a space between adjacent ones of a plurality of light-emitting elements respectively disposed in the plurality of sub-pixels.

According to various embodiments of the present disclosure, each of the plurality of light-emitting elements may include a micro LED.

According to various embodiments of the present disclosure, the light-blocking pattern part may have a structure in which a plurality of surface-treated black particles and molecules of silicone rubber are cross-linked with each other.

According to various embodiments of the present disclosure, each of the surface-treated black particles may include 3 to 6 vinyl groups at a surface thereof.

According to various embodiments of the present disclosure, the light-blocking pattern part may be coated on the substrate by a coating solution obtained by cross-linking of a plurality of surface-treated black particles and a silicone solution to each other, and the surface-treated black particles dispersed in the silicone solution may have a content in a range of 10% to 30% of the silicone solution.

According to various embodiments of the present disclosure, an optical density value of the light-blocking pattern part may be configured to be in a range from 1 to 3.

According to various embodiments of the present disclosure, a size of each of the surface-treated black particles may be configured to be in a range of about 200 nm to 500 nm, and/or a thickness of the light-blocking pattern part may be configured to be 5 μm or less.

According to various embodiments of the present disclosure, the plurality of connection wirings may comprise a connection wiring disposed between the first plate part and the second plate part adjacent to each other. The light-blocking pattern part may cover the connection wiring disposed between the first plate part and the second plate part adjacent to each other and may overlap a respective periphery of the first plate part and a respective periphery of the second plate part.

According to various embodiments of the present disclosure, the display apparatus may comprise a plurality of openings in the light-blocking pattern part. Each opening of the plurality of openings may extend through the light-blocking pattern part.

It will be apparent to those skilled in the art that various modifications and variations may be made in the apparatus of the present disclosure without departing from the scope of the disclosure. Thus, it is intended that the present disclosure covers the modifications and variations of this disclosure that come within the scope of the claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area and a non-display area adjacent to the display area, the substrate being variable;
a plurality of connection wirings disposed on the substrate;
a cover window disposed at least over the plurality of connection wirings; and
a light-blocking pattern part included in the cover window.

2. The display apparatus of claim 1, wherein the light-blocking pattern part is disposed such that the plurality of connection wirings are not visible to a viewer even when a stretching operation is repeated on the display apparatus.

3. The display apparatus of claim 1, further comprising:
a plurality of first plate parts disposed on the display area of the substrate, the plurality of first plate parts including a plurality of sub-pixels; and
a plurality of second plate parts disposed on the non-display area of the substrate.

4. The display apparatus of claim 3, wherein the plurality of first plate parts are arranged to be spaced apart from each other and configured to be relatively more rigid than the substrate, and the plurality of second plate parts are arranged to be spaced apart from each other and configured to be relatively more rigid than the substrate.

5. The display apparatus of claim 3, wherein the cover window further includes:
a first cover member; and
a second cover member,
wherein the light-blocking pattern part is between the first cover member and the second cover member.

6. The display apparatus of claim 5, wherein the second cover member covers the plurality of first plate parts, the plurality of second plate parts, and the plurality of connection wirings.

7. The display apparatus of claim 5, wherein the first cover member, the light-blocking pattern part, and the second cover member are integrated with each other.

8. The display apparatus of claim 5, wherein the first cover member and the second cover member have different elastic modulus.

9. The display apparatus of claim 8, wherein the elastic modulus of the first cover member is greater than the elastic modulus of the second cover member.

10. The display apparatus of claim 9, wherein the first cover member has an elastic modulus which does not exceed a maximum of 5 MPa, and the second cover member has an elastic modulus of 1 MPa or less.

11. The display apparatus of claim 5, wherein the first cover member includes an elastomer, the second cover member includes an optically cleared adhesive or an optically cleared resin, and the light-blocking pattern part includes an opaque material.

12. The display apparatus of claim 5, wherein the light-blocking pattern part is disposed in a boundary area between adjacent ones of the plurality of sub-pixels and disposed on the second cover member.

13. The display apparatus of claim 5, wherein the light-blocking pattern part may be disposed on an entire surface of the second cover member.

14. The display apparatus of claim 5, wherein the light-blocking pattern part has an opening through the light-blocking pattern part, the opening is a light emitting area where light emitted from a light-emitting element disposed in one of the plurality of sub-pixels is emitted, and the light-blocking pattern part is disposed on an entire surface of the second cover member excluding the opening.

15. The display apparatus of claim 1, wherein the plurality of connection wirings include:
a first connection wiring extending in a second direction and configured to be electrically connected to adjacent ones of the plurality of first plate parts to each other and be electrically connected to adjacent ones of the plurality of second plate parts to each other, respectively; and
a second connection wiring extending in a first direction different from the second direction and configured to electrically connect to adjacent ones of the plurality of first plate parts to each other and electrically connect to the first plate part and the second plate part adjacent to each other.

16. The display apparatus of claim 15, wherein the light-blocking pattern part is disposed at least over an area corresponding to the first connection wiring and the second connection wiring.

17. The display apparatus of claim 1, wherein each of the plurality of connection wirings includes a shape in which irregularities are continuously repeated or a concave-convex shape.

18. The display apparatus of claim 17, wherein each of the plurality of connection wirings extends in a wave shape or a zigzag shape.

19. The display apparatus of claim 5, wherein the cover window further includes an optical functional film layer disposed on the first cover member.

20. The display apparatus of claim 3, further comprising a plurality of light-emitting elements respectively disposed at the plurality of sub-pixels and spaced apart from each other,
wherein a portion of the light-blocking pattern part is disposed between adjacent ones of the plurality of light-emitting elements.

21. The display apparatus of claim 15, wherein the light-blocking pattern part includes a first pattern part and a second pattern part, the first pattern part is disposed to overlap with the first connection wiring and the second connection wiring, and has a shape corresponding to that of each of the first connection wiring and the second connection wiring, the second pattern part is disposed in a boundary area between adjacent ones of the plurality of sub-pixels.

22. The display apparatus of claim 15, wherein the light-blocking pattern part covering a boundary area between adjacent ones of the plurality of sub-pixels, the first connection wiring, and the second connection wiring is disposed on the first plate part and the second plate part.

23. The display apparatus of claim 3, wherein the light-blocking pattern part is disposed to fill a space between adjacent ones of a plurality of light-emitting elements respectively disposed in the plurality of sub-pixels.

24. The display apparatus of claim 20, wherein each of the plurality of light-emitting elements includes a micro LED.

25. The display apparatus of claim 1, wherein the light-blocking pattern part includes a structure in which a plurality of surface-treated black particles and molecules of silicone rubber are cross-linked with each other.

26. The display apparatus of claim 25, wherein each of the surface-treated black particles includes 3 to 6 vinyl groups at a surface thereof.

27. The display apparatus of claim 1, wherein the plurality of connection wirings comprise a connection wiring disposed between the first plate part and the second plate part adjacent to each other, and
wherein the light-blocking pattern part covers the connection wiring disposed between the first plate part and the second plate part adjacent to each other and overlaps a respective periphery of the first plate part and a respective periphery of the second plate part.

28. The display apparatus of claim 1, further comprising a plurality of openings in the light-blocking pattern part,
wherein each opening of the plurality of openings extends through the light-blocking pattern part.
